(19) United States
(12) Patent Application Publication
(10) Pub. No.: US 2010/0327363 A1
(43) Pub. Date: Dec. 30, 2010

(54) SEMICONDUCTOR DEVICE AND METHOD FOR FABRICATING THE SAME

(75) Inventor: Takashi NAKABAYASHI, Osaka (JP)

Correspondence Address: MCDERMOTT WILL & EMERY LLP, 600 13TH STREET, NW, WASHINGTON, DC, 20005-3096, US

(73) Assignee: Panasonic Corporation, Osaka (JP)

(21) Appl. No.: 12/874,770

(22) Filed: Sep. 2, 2010

Related U.S. Application Data
(63) Continuation of application No. PCT/JP2009/002108, filed on May 14, 2009.

(30) Foreign Application Priority Data
May 22, 2008 (JP) 2008-134271

(51) Int. Cl. H01L 27/088; H01L 21/8234

(52) U.S. Cl. 257/368; 438/294; 257/E27.06; 257/E21.616

(57) ABSTRACT

Sidewalls are formed on side surfaces of fin-shaped active regions, and then substrate regions surrounded by a device isolation groove are formed, where the widths of each substrate region in a channel length direction and in a channel width direction are respectively larger than those of the active region. Next, the sidewalls are removed, the device isolation groove and regions between the active regions are filled with an insulator film, and the insulator film is etched such that upper surfaces of the substrate regions are exposed. Next, an impurity is implanted in an upper portion of the substrate regions to form a punch through stopper diffusion layer, thereby forming fin transistors.

### CROSS-REFERENCE TO RELATED APPLICATION

This is a continuation of PCT International Application PCT/JP2009/002108 filed on May 14, 2009, which claims priority to Japanese Patent Application No. 2008-134271 filed on May 22, 2008. The disclosures of these applications including the specifications, the drawings, and the claims are hereby incorporated by reference in their entirety.

### BACKGROUND

The technique described in the present specification relates to semiconductor devices and methods for fabricating the same, and more specifically to fin transistors and methods for fabricating the same.

In fin transistors, an upper surface portion and side surface portions of an thin, fin-shaped active region are used as a channel of a MOS transistor, so that it is possible to obtain a large drive current. Moreover, a gate voltage is applied from three directions, so that gate controllability is improved. Therefore, the short-channel effect, which is the biggest problem in miniaturization of devices, can be reduced, and thus the fin transistors are expected to serve as next-generation devices.

Generally, fin transistors are formed on a silicon on insulator (SOI) substrate, but an oxide film having a low thermal conductivity is interposed between the substrate and the transistors, so that it is difficult to release heat generated at the transistors. For this reason, bulk fin transistors in which fin transistors are formed on a bulk substrate have been provided in recent years.

FIGS. 5A-5D and FIGS. 6A-6D are cross-sectional views illustrating processes in a general method for fabricating p-channel type fin transistors formed on a bulk substrate. FIG. 7 is a view illustrating a layout of conventional fin transistors. In FIGS. 5A-5D and FIGS. 6A-6D, drawings on the left are cross-sectional views taken along the line a-a′ of FIG. 7, and drawings on the right are cross-sectional views taken along the line b-b′ of FIG. 7. The method for fabricating the conventional fin transistors is as follows.

First, as illustrated in FIG. 5A, a silicon oxide film 111 having a thickness of 10 nm and a silicon nitride film 112 having a thickness of 50 nm are deposited sequentially on an n-type silicon substrate 110. Next, using a photoresist as a mask, the silicon nitride film 112 and the silicon oxide film 111 are patterned, and further, the silicon substrate 110 is etched by 200 nm to form a groove 113 and fin-shaped transistor active regions 116.

Next, as illustrated in FIG. 5B, the groove 113 is filled with a silicon oxide film 114. Then, using the silicon nitride film 112 as a stopper, a device upper surface is planarized by chemical mechanical polishing (CMP).

Subsequently, as illustrated in FIG. 5C, phosphorus (P) ions are implanted under conditions that the implantation energy is 80 keV, and the dose amount is 6×10¹³ cm⁻² to form an n-type punch through stopper diffusion layer 115 in regions of the silicon substrate 110 which are located under the silicon nitride film 112 and the silicon oxide film 111.

Next, as illustrated in FIG. 5D, using the silicon nitride film 112 as a mask, the silicon oxide film 114 is etched back to a depth of 100 nm from an upper surface of the silicon substrate 110 to expose the transistor active regions 116.

Next, as illustrated in FIG. 6A, an insulator film having a thickness of 2 nm and a polysilicon film having a thickness of 100 nm are deposited and then patterned to form a gate insulating film 117 and a gate electrode 118 on upper surfaces and side surfaces of the transistor active regions 116 and on the silicon oxide film 114.

Next, as illustrated in FIG. 6B, boron (B) ions are implanted to form an LDD diffusion layer 119 in regions of the transistor active regions 116 which are located on both sides of the gate electrode 118.

Subsequently, as illustrated in FIG. 6C, a silicon nitride film is deposited over the substrate (the fin transistors in the course of fabrication) and then etched back to form sidewalls 120 on side surfaces of the LDD diffusion layer 119 and on side surfaces of projecting portions of the gate electrode 118. Subsequently, using the gate electrode 118 and the sidewalls 120 as a mask, B ions are implanted to form source/drain diffusion regions 121 in regions of the LDD diffusion layer 119 which are located laterally to the gate electrode 118 and the sidewalls 120.

Next, as illustrated in FIG. 6D, an interlayer insulating film 122 is deposited over the substrate. Then, contacts 123 and metal interconnects 124 are formed in desired locations.

In the p-channel type fin transistors fabricated using the method described above, substrate portions of the transistors are part of the silicon substrate, so that heat generated at the transistors can be easily released via the substrate. Therefore, deterioration of device properties which is caused by the generation of heat, for example, degradation in mobility, increase in leakage current, etc. can be reduced.

### SUMMARY

However, in conventional semiconductor devices, since the punch through stopper diffusion layer 115 is required to be formed under the source/drain diffusion regions 121 at a depth of 100 nm (fin height) from the upper surfaces of the transistor active regions 116, P susceptible to thermal diffusion has to be implanted at a high energy of 80 keV. Thus, the punch through stopper diffusion layer 115 largely expands, thereby increasing the impurity concentration of channels of the fin transistors. This lowers the mobility, and moreover, the threshold voltage increases, thereby causing a trouble that the drivability of the transistors is lowered.

In a fin-type transistor according to an example embodiment of the present invention, the drivability is improved without increasing the impurity concentration of a channel portion.

A semiconductor device according to an example of the present invention includes: a semiconductor substrate of a first conductivity type; an active region having a fin shape and formed in an upper portion of the semiconductor substrate; a gate electrode formed on side surfaces and upper surface of a portion of the active region with a gate insulating film interposed therebetween, where the gate electrode extends over the semiconductor substrate in a channel width direction when viewed in plan; a substrate region formed in a region of the semiconductor substrate which is located directly under the active region, where widths in the channel width direction and a channel length direction of the substrate region are respectively larger than those of the active region; first impurity diffusion regions of a second conductivity type formed in regions of the active region which are located on both sides of the gate electrode; and a second impurity diffusion region of the first conductivity type formed in a region which is an upper portion of the substrate region and which is adjacent to the active region inclusive of the first impurity diffusion regions, where the second impurity diffusion region is located directly under the first impurity diffusion regions.

With this configuration, the substrate region whose widths in the channel width direction and the channel length direction are respectively larger than those of the fin-shaped active region is formed under the active region, so that expansion of the second impurity diffusion region (punch through stopper diffusion layer) formed under the first impurity diffusion regions (source/drain regions) at the time of fabricating the device is reduced. Thus, the impurity concentration of the channel portion can be limited to a low value, so that it is possible to reduce the degradation of the drivability in the case where the semiconductor device is a fin transistor formed on, for example, a bulk substrate.

A method for fabricating a semiconductor device according to an example of the present invention includes: (a) etching an upper portion of a semiconductor substrate using a first mask formed on the semiconductor substrate to form an active region having a fin shape; (b) forming sidewalls on side surfaces of the active region; (c) etching the semiconductor substrate using the first mask and the sidewalls as a mask to form a groove such that a substrate region whose widths in a channel width direction and a channel length direction are respectively larger than those of the active region is formed in a region of the semiconductor substrate which is located directly under the active region; (d) removing a portion of the first mask and the sidewalls, and then forming an insulator film filling the groove formed in the semiconductor substrate at (c); and (e) after (d), implanting ions of an impurity of a first conductivity type using a portion of the first mask as a mask to form a second impurity diffusion region in a region which is an upper portion of the substrate region and which is adjacent to the active region.

With this method, the ions of the impurity of the first conductivity type can be implanted at a low energy, for example, with the substrate region which is a portion of the semiconductor substrate being exposed, so that the formation region of the second impurity diffusion region serving as a punch through stopper diffusion layer can be smaller than in the case where the second impurity diffusion region is formed using a conventional method. Thus, when the method according to the example of the present invention is used, the impurity of the first conductivity type is less diffused in the channel portion of the semiconductor device, so that increase of the threshold value can be limited, or degradation of the mobility can be reduced.

In the semiconductor device according to the example of the present invention and the method for fabricating the same, the second impurity diffusion region can be located directly under the first impurity diffusion regions (source and drain) and in their periphery, so that it is possible to limit the impurity concentration of the channel portion to a low value. Thus, it is possible to reduce the degradation of the drivability of the fin transistor formed on the bulk substrate.

### BRIEF DESCRIPTION OF THE DRAWINGS

FIGS. 1A-1D are cross-sectional views illustrating a method for fabricating p-channel type fin transistors formed on a bulk substrate according to an embodiment of the present invention.

FIGS. 2A-2D are cross-sectional views illustrating the method for fabricating the p-channel type fin transistors according to the embodiment of the present invention.

FIG. 3 is a view illustrating a layout of the fin transistors according to the embodiment of the present invention.

FIGS. 4A and 4B are views illustrating the net impurity profiles in a depth direction respectively under a gate electrode and under source/drain diffusion regions of the p-channel type fin transistor according to the embodiment.

FIGS. 5A-5D are cross-sectional views illustrating processes in a general method for fabricating p-channel type fin transistors formed on a bulk substrate.

FIGS. 6A-6D are cross-sectional views illustrating processes in the general method for fabricating the p-channel type fin transistors formed on the bulk substrate.

FIG. 7 is a view illustrating a layout of conventional fin transistors.

FIG. 8 is a view illustrating the net impurity profiles in a depth direction respectively under a gate electrode and under source/drain diffusion regions of the conventional p-channel type fin transistor.

### DETAILED DESCRIPTION

### Embodiment

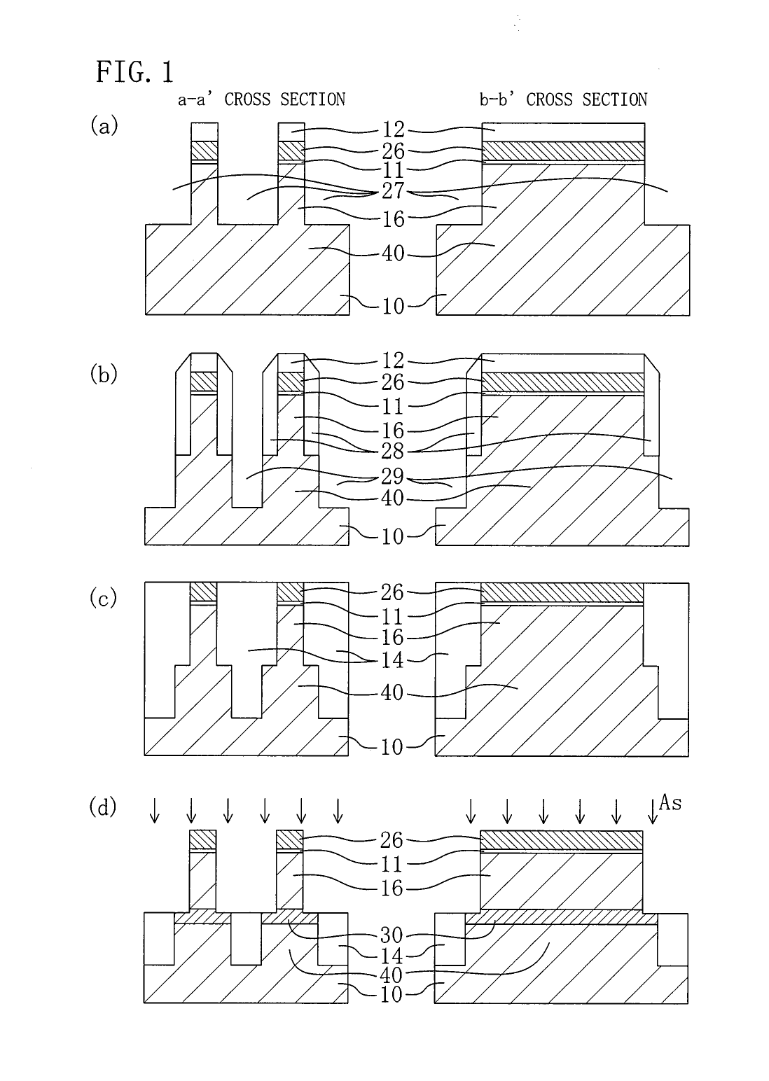

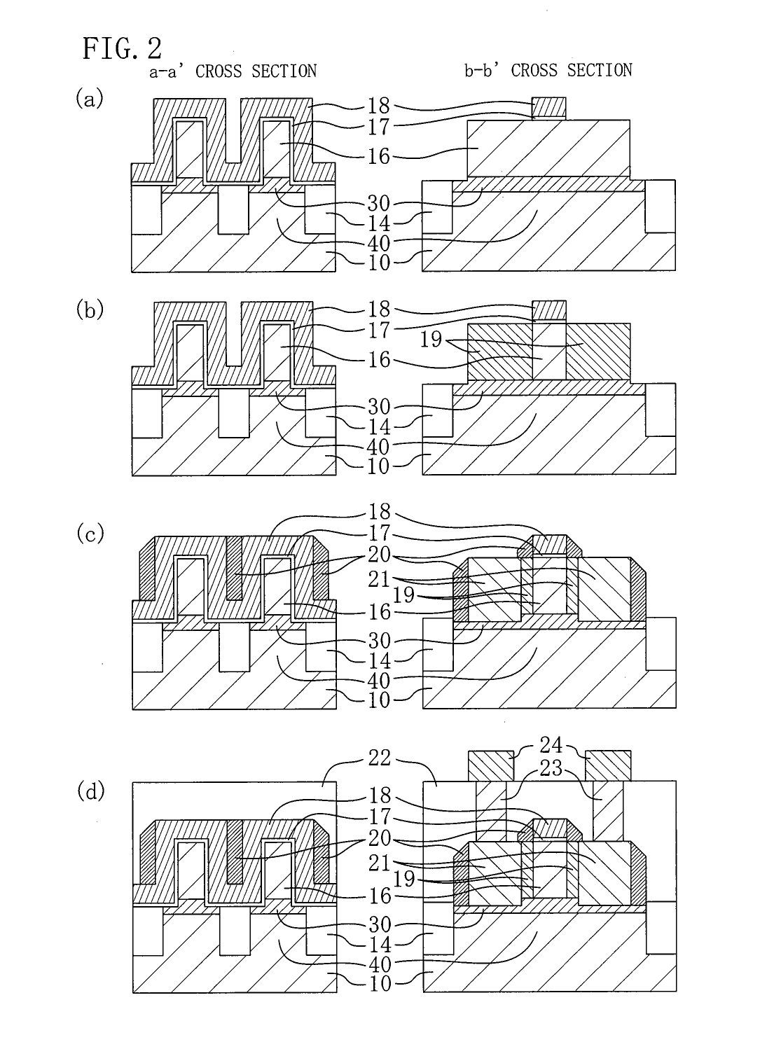

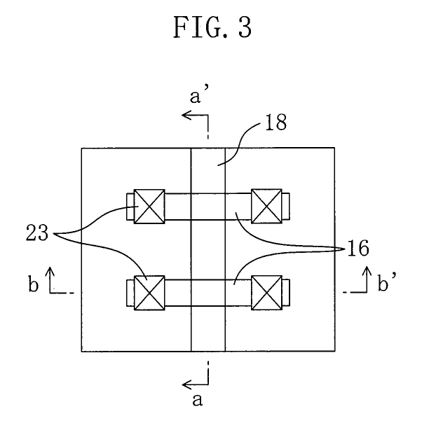

FIGS. 1A-1D and FIGS. 2A-2D are cross-sectional views illustrating a method for fabricating p-channel type fin transistors formed on a bulk substrate according to an embodiment of the present invention. FIG. 3 is a view illustrating a layout of the fin transistors of the present embodiment. In FIGS. 1A-1D and FIGS. 2A-2D, drawings on the left are cross-sectional views taken along the line a-a′ (channel width direction) of FIG. 3, and drawings on the right are cross-sectional views taken along the line b-b′ (channel length direction) of FIG. 3. As illustrated in FIG. 2D and FIG. 3, each fin transistor of the present embodiment includes a narrow, fin-shaped transistor active region 16 formed in an upper portion of an n-type silicon substrate, and a gate electrode 18 extending in the channel width direction. The gate electrode 18 is formed on side surfaces and an upper surface of the transistor active region 16 with a gate insulating film interposed therebetween. Moreover, a plurality of contacts 23 which are connected to the transistor active regions 16 is provided. A method for fabricating the fin transistors of the present embodiment will be described below.

First, as illustrated in FIG. 1A, a silicon oxide film 11 having a thickness of 10 nm, an amorphous silicon film 26 having a thickness of 50 nm, and a silicon nitride film 12 having a thickness of 50 nm are formed sequentially on an n-type silicon substrate 10. Next, using a photoresist as a mask, the silicon nitride film 12, the amorphous silicon film 26, and the silicon oxide film 11 are patterned, and further, the n-type silicon substrate 10 is etched by about 100 nm to form a groove 27 and fin-shaped transistor active regions 16. The width (the length in the cross section a-a′) of each transistor active region 16 is set to about 10 nm. Note that a polysilicon film may be formed in this process instead of the amorphous silicon film 26.

Next, as illustrated in FIG. 1B, a silicon nitride film having a thickness of 50 nm is deposited on the substrate. Then, the silicon nitride film is etched back to form silicon nitride film sidewalls 28 on the side surfaces of the transistor active regions 16, the silicon oxide film 11, the amorphous silicon film 26, and the silicon nitride film 12. Subsequently, using the silicon nitride film 12 and the silicon nitride film sidewalls 28 as a mask, the n-type silicon substrate 10 is etched by about 100 nm to form a device isolation groove 29. In this way, substrate regions 40 made of silicon are formed under the transistor active regions 16. Each substrate region 40 has widths respectively larger than those of the transistor active region 16 in the channel width direction and in the channel length direction, and has, for example, a fin shape.

Next, as illustrated in FIG. 1C, the silicon nitride film sidewalls 28 and the silicon nitride film 12 are removed by hot phosphoric acid. Subsequently, the groove 27 and the device isolation groove 29 are filled with an insulator film such as a silicon oxide film 14, and a substrate upper surface is planarized by CMP using the amorphous silicon film 26 as a stopper.

Next, as illustrated in FIG. 1D, using the amorphous silicon film 26 as a mask, the silicon oxide film 14 is etched back to a depth of about 100 nm from an upper surface of the n-type silicon substrate 10 to expose bottom portions of the n-type silicon substrate 10 where the silicon nitride film sidewalls 28 have been removed. Next, arsenic (As) ions are implanted in a manner substantially perpendicular to a principal surface of the n-type silicon substrate 10 under conditions that the implantation energy is 20 keV, and the dose amount is 1×10¹³ cm⁻². The As ions go about 6 nm in the transverse direction in the drawing on the left of FIG. 1D immediately after the implantation, so that impurity regions formed by the As implanted from both the side surfaces of the transistor active regions 16 each having a thickness of 10 nm connect under bottom portions of the transistor active regions, thereby forming an n-type punch through stopper diffusion layer 30.

Next, as illustrated in FIG. 2A, the amorphous silicon film 26 and the silicon oxide film 11 are removed. After that, an insulator film having a thickness of 2 nm and a polysilicon film having a thickness of 100 nm are deposited and then patterned to form a gate insulating film 17 made of the insulator film and a gate electrode 18 made of the polysilicon film on an upper surface of the silicon oxide film 14 and on the side surfaces and the upper surfaces of the transistor active regions 16.

Next, as illustrated in FIG. 2B, B ions are implanted to form an LDD diffusion layer 19 in regions of the transistor active regions 16 which are located on both sides of the gate electrode 18 in the channel length direction.

Next, as illustrated in FIG. 2C, a silicon nitride film is deposited over the substrate (the fin transistors in the course of fabrication). Then, a silicon nitride film is etched back to form sidewalls 20 on side surfaces of the LDD diffusion layer 19 and on side surfaces of projecting portions of the gate electrode 18. Subsequently, B ions are implanted to form source/drain diffusion regions 21 in regions of the LDD diffusion layer 19 which are located laterally to the gate electrode 18 and the sidewalls 20. Portions of the LDD diffusion layer 19 which are located under the sidewalls 20 formed on the side surfaces of the gate electrode 18 remain with their impurity concentration being low.

Next, as illustrated in FIG. 2D, an interlayer insulating film 22 is deposited over the substrate. Then, contacts 23 and metal interconnects 24 are formed in desired locations.

As illustrated in FIG. 2D and FIG. 3, each fin transistor of the present embodiment fabricated using the method above includes: the n-type silicon substrate (semiconductor substrate) 10; the fin-shaped transistor active region 16 formed in an upper portion of the n-type silicon substrate 10; the gate electrode 18 formed on the side surfaces and on the upper surface of a portion of the transistor active region 16 with the gate insulating film 17 interposed therebetween, where the gate electrode 18 extends over the n-type silicon substrate 10 in the channel width direction; the sidewalls 20 formed on the side surfaces of the gate electrode 18; the LDD diffusion layer 19 formed in regions of the transistor active region 16 which are located under the sidewalls 20 lateral to the gate electrode 18, where the LDD diffusion layer 19 contains a p-type impurity (e.g., boron); the source/drain diffusion regions (first impurity diffusion regions) 21 formed in regions of the transistor active region 16 which are located on both sides of the gate electrode 18 and are adjacent to the LDD diffusion layer 19, where the source/drain regions 21 contain the p-type impurity at a higher concentration than that in the LDD diffusion layer 19; the fin-shaped substrate region 40 formed in a region of the n-type silicon substrate 10 which is located directly under the transistor active region 16, where the widths of the fin-shaped substrate region 40 are respectively larger than those of the transistor active region 16 in the channel width direction and in the channel length direction; the silicon oxide film 14 filled in the groove formed in the n-type silicon substrate 10 and surrounding the substrate region 40; and the punch through stopper diffusion layer (second impurity diffusion region) 30 formed in an upper portion of the substrate region 40 under the transistor active region 16 inclusive of the source/drain diffusion regions 21, where the punch through stopper diffusion layer 30 contains an n-type impurity (e.g., As). In an integrated circuit, a plurality of fin transistors each including the fin-shaped transistor active region 16 is disposed in the channel width direction.

Next, advantages of the fin transistor of the present embodiment and the method for fabricating the same will be described.

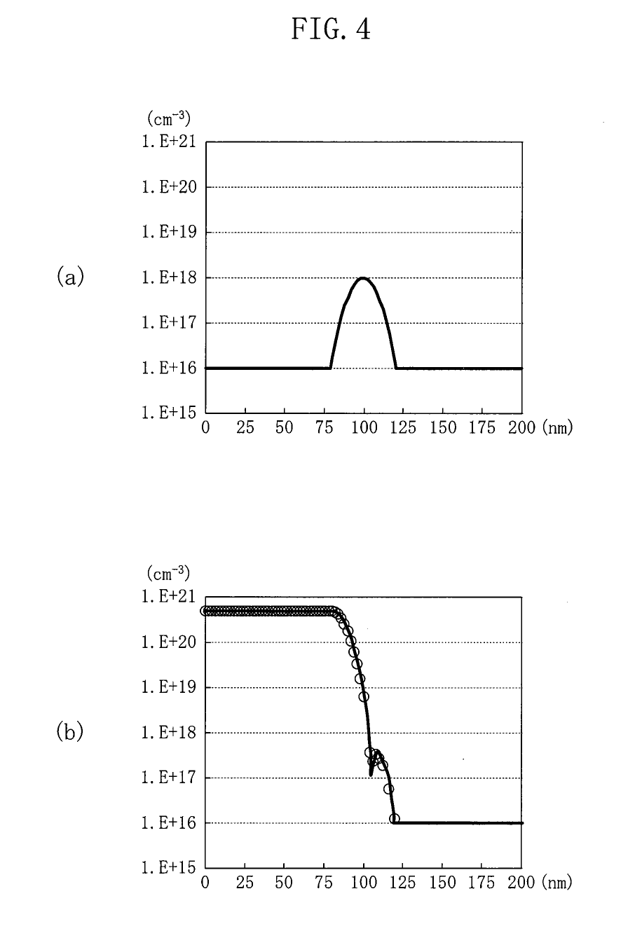

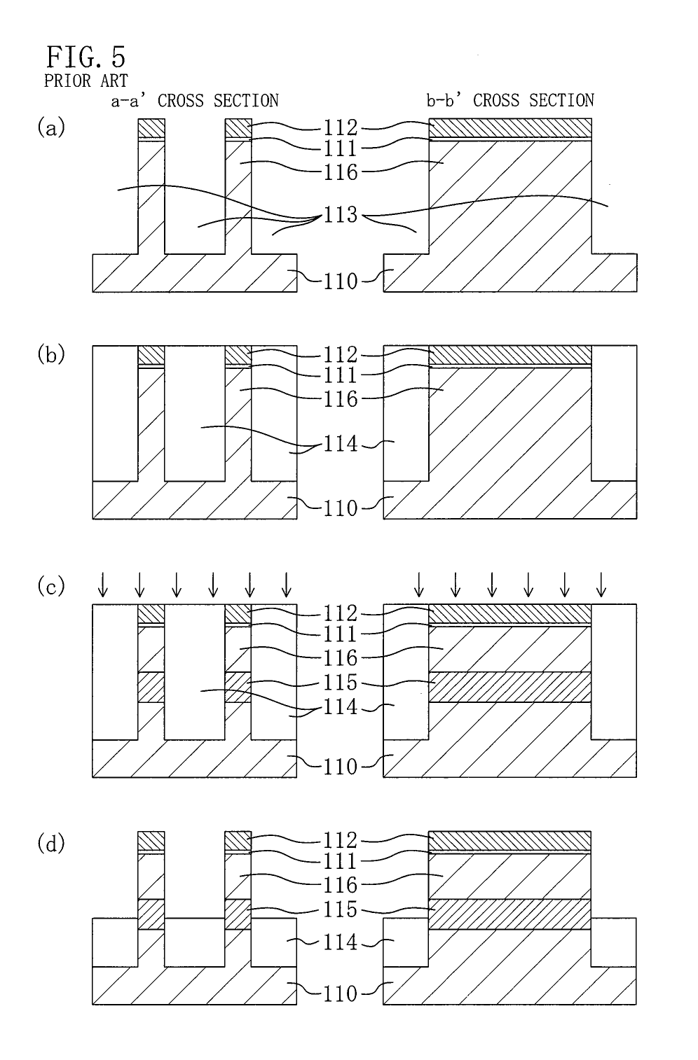

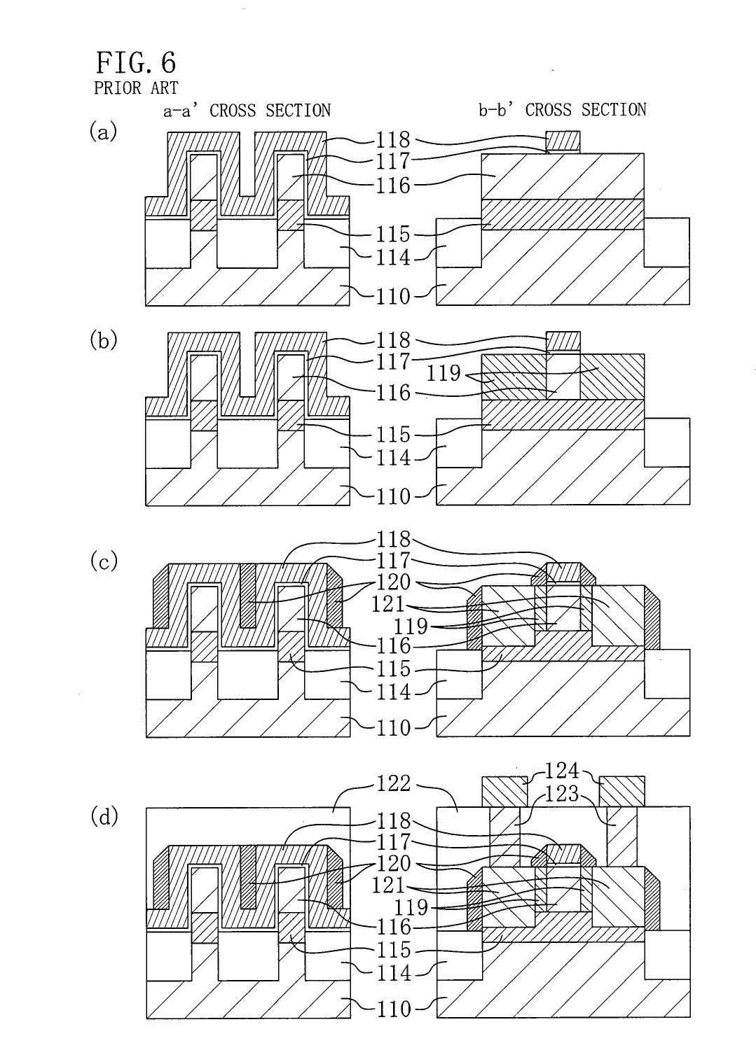

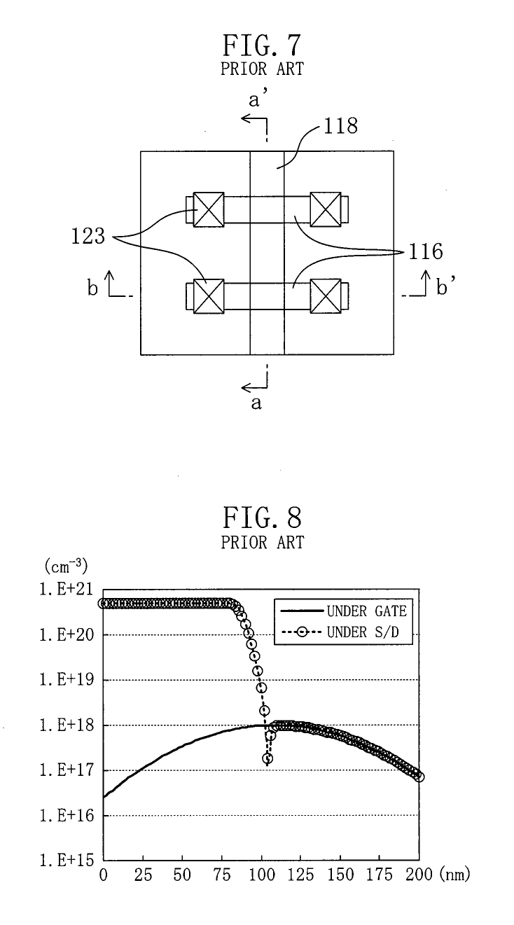

FIGS. 4A and 4B are views illustrating the net impurity profiles in a depth direction respectively under the gate electrode and under the source/drain diffusion regions of the p-channel type fin transistor of the present embodiment. FIG. 8 is a view illustrating the net impurity profiles in a depth direction respectively under the gate electrode and the source/drain diffusion regions of a conventional p-channel type fin transistor. In FIGS. 4A and 4B, the level at the upper surface of the transistor active region 16 is defined as a depth of 0 nm. FIG. 4A for the net impurity profile under the gate electrode shows that the punch through stopper diffusion layer 30 is localized in a position at a depth of 100 nm. FIG. 4B for the net impurity profile under the source/drain diffusion regions shows that the punch through stopper diffusion layer 30 is formed in contact with bottom portions of the source/drain diffusion regions 21 located at a depth of 100 nm. Moreover, the impurity concentration of the n-type silicon substrate 10 is about 1×10¹⁶ cm⁻³.

In an ordinary technique, for example, phosphorus (P) has to be implanted at a relatively high energy of 80 keV under the condition that the dose amount is, for example, 5×10¹³ cm⁻² in order to form a punch through stopper diffusion layer. This broadens the range of the impurity profile immediately after the implantation. Moreover, since P has a high thermal diffusion coefficient, thermal treatment at the time of, for example, activating the source/drain diffusion regions further expands the punch through stopper diffusion layer. As a result, as illustrated in FIG. 8, the n-type impurity concentration of a channel portion is increased to 1×10¹⁷ cm⁻³-1×10¹⁸ cm⁻³. Note that since the ion implantation is performed through a thick film, very high implantation energy is required when As having a larger atomic radius is implanted instead of P. Therefore, the range of the implantation profile is significantly broadened, which may leave significant damage in the substrate.

In contrast, the technique of the present embodiment allows an n-type impurity to be implanted directly in a portion directly under the transistor active region 16 (a portion which will be in contact with bottom portions of the source/drain diffusion regions 21) as illustrated in the process of FIG. 1D. Therefore, a p-type impurity can be implanted at a low energy of, for example, 20 keV under the condition that the dose amount is about 1×10¹³ cm⁻², so that it is possible to narrow the profile width immediately after the implantation. That is, it is possible to provide the punch through stopper diffusion layer 30 only in the portion directly under the transistor active region 16 inclusive of the source/drain diffusion regions 21. Moreover, it is possible to implant impurities directly in desired regions, which allows As whose thermal diffusion coefficient is lower than that of P to be used as an n-type impurity, so that it the broadening of the range of the impurity profile caused by the thermal treatment can be reduced.

As a result, as illustrated in FIG. 4A, the n-type impurity concentration of the channel portion can be limited to about 1×10¹⁶ cm⁻³. Here, the channel portion is formed in an extent within a depth of 75 nm from the upper surface of the transistor active region 16. Therefore, the threshold voltage of the transistor can be limited to a low value, and mobility degradation caused by carrier scattering by the impurity can be reduced, so that it is possible to form a bulk fin transistor having a high drivability.

Moreover, the fin transistors of the present embodiment are formed on a bulk substrate, so that heat generated by driving the fin transistors can be released easily in a direction of the bulk substrate, thereby allowing the heat dissipation property to be improved in comparison to the case where fin transistors are provided on a SOI substrate.

Note that in the fin transistors of the present embodiment, the length of each transistor active region 16 in the channel width direction is not particularly limited to, but preferably such a length that impurity regions formed by As ions implanted from both sides of the transistor active region 16 connect under the transistor active region 16 to form the punch through stopper diffusion layer 30. When implanting As, it is particularly preferable that the length of the transistor active region 16 in the channel width direction is specifically about 10 nm. Moreover, the ion implantation energy to form the punch through stopper diffusion layer 30 may be varied according to the width of the transistor active region 16.

Moreover, the case where the fin transistor is p-channel type has been described above, but applying the same configuration to an n-channel type transistor using In can reduce the expansion of a p-type punch through stopper diffusion layer, so that it is possible to improve the drivability of the transistor.

Note that in the process illustrated in FIG. 1B, sidewalls made of, for example, a polysilicon film, an amorphous silicon film, or the like may be formed instead of the silicon nitride film sidewalls 28. Any material having etch selectivity with respect to the substrate can preferably be used.

Moreover, the semiconductor device and the method for fabricating the same described above are examples of the present invention, and the materials, the size, the shape, and the like of each member may be modified within the scope of the present invention.

For example, as a bulk fin transistor having high drivability and low power consumption and a method for fabricating the same, the semiconductor device and the method for fabricating the same according to an example of the present invention described above are useful to a variety of semiconductor devices on which transistors are mounted, and apparatuses on which the semiconductor devices are mounted.

What is claimed is:

1. A semiconductor device comprising:
a semiconductor substrate of a first conductivity type;
an active region having a fin shape and formed in an upper portion of the semiconductor substrate;
a gate electrode formed on side surfaces and upper surface of a portion of the active region with a gate insulating film interposed therebetween, where the gate electrode extends over the semiconductor substrate in a channel width direction when viewed in plan;
a substrate region formed in a region of the semiconductor substrate which is located directly under the active region, where widths in the channel width direction and a channel length direction of the substrate region are respectively larger than those of the active region;
first impurity diffusion regions of a second conductivity type formed in regions of the active region which are located on both sides of the gate electrode; and
a second impurity diffusion region of the first conductivity type formed in a region which is an upper portion of the substrate region and which is adjacent to the active region inclusive of the first impurity diffusion regions, where the second impurity diffusion region is located directly under the first impurity diffusion regions.

2. The semiconductor device of claim 1, wherein the substrate region is surrounded by an insulator film.

3. the semiconductor device of claim 1, wherein the second impurity diffusion region contains As.

4. the semiconductor device of claim 1, wherein the second impurity diffusion region contains In.

5. A method for fabricating a semiconductor device, comprising:
(a) etching an upper portion of a semiconductor substrate using a first mask formed on the semiconductor substrate to form an active region having a fin shape;
(b) forming sidewalls on side surfaces of the active region;
(c) etching the semiconductor substrate using the first mask and the sidewalls as a mask to form a groove such that a substrate region whose widths in a channel width direction and a channel length direction are respectively larger than those of the active region is formed in a region of the semiconductor substrate which is located directly under the active region;
(d) removing a portion of the first mask and the sidewalls, and then forming an insulator film filling the groove formed in the semiconductor substrate at (c); and
(e) after (d), implanting ions of an impurity of a first conductivity type using a portion of the first mask as a mask to form a second impurity diffusion region in a region which is an upper portion of the substrate region and which is adjacent to the active region.

6. The method of claim 5, wherein at (d), depositing an insulator, and then etching back the insulator such that the substrate region is exposed to form the insulator film.

7. The method of claim 5, further comprising:
(f) after (e), forming a gate insulating film extending on the insulator film and on side surfaces and an upper surface of the diffusion region, and forming a gate electrode on the gate insulating film such that the gate electrode extends along the side surfaces and the upper surface of the diffusion region in a channel width direction when viewed in plan; and
(g) implanting ions of an impurity of a second conductivity type using the gate electrode as a mask to form first impurity diffusion regions in regions of the active region which are located on both sides of the gate electrode.

8. The method of claim 5, wherein the first mask used at (a) is a layered film including at least a silicon nitride film and a polysilicon or amorphous silicon film.

9. The method of claim 5, wherein the sidewall formed at (b) contains silicon nitride, polysilicon, or amorphous silicon.
